(19) United States
(12) Patent Application Publication
(10) Pub. No.: US 2006/0289202 A1
(43) Pub. Date: Dec. 28, 2006

(54) Stacked microvias and method of manufacturing same

(75) Inventors: Timothy M. Takeuchi, Chandler, AZ (US); Sriram Srintvasan, Chandler, AZ (US); Sandeep B. Sanf, Chandler, AZ (US)

Correspondence Address: VENABLE LLP, P.O. BOX 34385, WASHINGTON, DC, 20043-9998, US

(73) Assignee: Intel Corporation, Santa Clara, CA (US)

(21) Appl. No.: 11/165,482

(22) Filed: Jun. 24, 2005

(51) Int. Cl. H05K 1/11; H05K 3/42

(52) U.S. Cl. 174/262; 29/852

(57) ABSTRACT

A flip chip package may include stacked vias in which the diameter D1 of the outermost via is less than the diameter D2 of the innermost via. The ratio D2/D1, for example, may be 1.5 to 2.

### BACKGROUND OF THE INVENTION

Embodiments of the present invention relate generally to flip chip and chip scale technologies for creating single chip or multi-chip modules (MCM), integrated circuit (IC) cards, memory cards, very dense surface mount assemblies, and the like.

More particularly, embodiments of the invention relate to stacked vias and methods of manufacturing same for use in chip scale packaging variations, which include but are not limited to flip chip packages, high density interconnect (HDI) packages, micro ball grid array (μBGA) packages, micro surface mount technology (MSMT) packages, and slightly larger than integrated circuit carriers (SLICC) packages.

With changes in sophistication of electronic equipment over the years, manufacturers of electronic component packages have produced higher density circuits in smaller packages. High interconnect density on electronic component packages is provided by utilizing multi-layer circuits separated by a dielectric material. The demand for manufacturing semiconductor IC devices such as computer chips with high circuit speed, high packing density, and low power dissipation requires the downward scaling of feature sizes in ultra-large-scale integration (ULSI) and very-large-scale integration (VLSI) structures. This demand presents an acute challenge to retain and advance the integrity of the prior-generation electronic component packages while dramatically increasing the processing capability of the circuitry.

For example, in the field of next-generation small portable electronic communication devices, HDI technology may be fast becoming an enabling technology. The methods used in this field employ many different dielectrics and via fabrication technologies. Therefore, the effect of the proximity of microvias to plated through holes (PTHs), and their effect on the reliability of the microvias may be impacted. Particular methods of forming the microvias by differing laser ablation (e.g., YAG laser drilling and YAG-CO2 laser drilling) and photoimaging technologies, as well as the specific materials (e.g., non-glass reinforced and glass reinforced dielectric materials) that make up the dielectric layers, may also have an impact. As a result, it has been found that the location of microvias vis-à-vis PTHs and the size of such microvias may indeed have an effect on the reliability of those microvias.

Stacked via configurations may be subjected to thermal stresses and strains during their assembly process and during subsequent thermal cycling. This effect may be mainly caused by the high coefficient of thermal expansion (CTE) mismatch between the dielectric materials of the substrate (i.e., α_{dielectric}) and the copper vias (i.e., α_{copper}) and the high stiffness of both materials. The mechanical strains and stresses generated by this CTE mismatch may usually be the driving force for package failure and therefore, may have to be minimized. The typical problems that may be experienced may be via cracking under too high stresses and copper failure under thermal cycling conditions. In turn, these problems may cause delamination of the via interfaces.

### BRIEF DESCRIPTION OF THE DRAWINGS

Preferred embodiments of the invention will now be described in connection with the associated drawings, in which:

FIG. 1 depicts one configuration of a multi-layer printed circuit board in which embodiments of the present invention may be implemented;

FIG. 2 depicts one configuration of a typical HDI multi-layer circuit in which embodiments of the present invention may be implemented;

FIG. 3 depicts one configuration of stacked vias according to embodiments of the present invention;

FIG. 4 depicts another configuration of stacked vias according to embodiments of the present invention;

FIG. 5 depicts a graph showing a range of ratios of the diameter D2 of an innermost via in a stack of vias according to embodiments of the present invention to the diameter D1 of an outermost via; and

FIG. 6 depicts a block diagram of a system according to embodiments of the present invention.

### DETAILED DESCRIPTION OF PREFERRED EMBODIMENTS

In the following description and claims, the terms “connected” and “coupled,” along with their derivatives, may be used. It should be understood that these terms are not intended as synonyms for each other. Rather, in particular embodiments, “connected” may be used to indicate that two or more elements are in direct physical or electrical contact with each other. In contrast, “coupled” may mean that two or more elements are in direct physical or electrical contact with each other or that the two or more elements are not in direct contact but still cooperate or interact with each other.

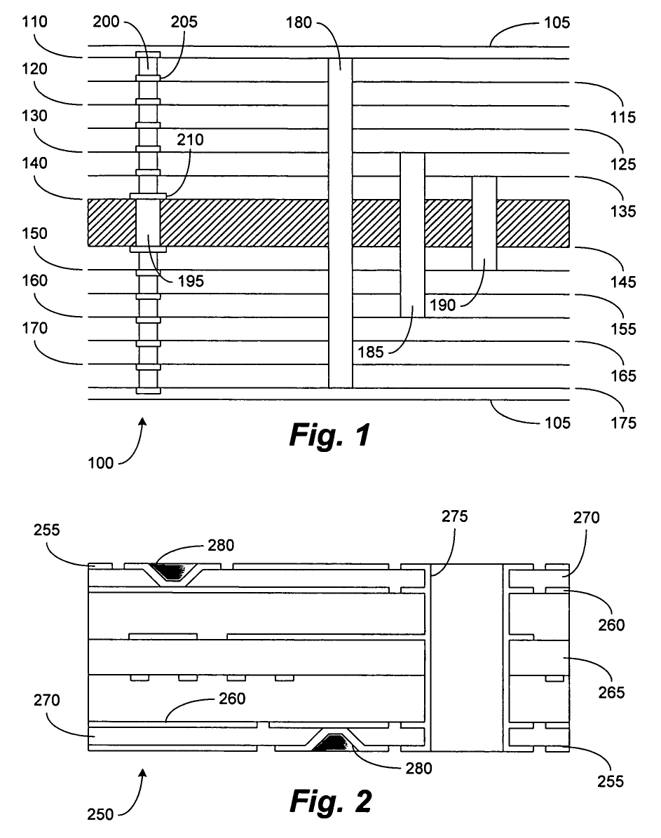

FIG. 1 depicts a multi-layer printed circuit board (PCB) 100 in which embodiments of the present invention may be implemented. In general, electronic component packages such as PCB 100 may be manufactured using conductive traces on the surface 105, or X-Y plane, of the electrical circuit's substrate to connect discrete electronic devices. Distinct layers 110, 115, 120, 125, 130, 135, 140, 145, 150, 155, 160, 165, 170, and 175 of the package may be vertically connected by through-hole interconnects 180, or vias 185, 190, 195, and 200. Conductive vias may be traditionally created by drilling though a stack of circuit substrate layers, then plating the wall of the via with an electrically conductive material such as copper. Such multi-layered circuits may contain as many as 100-200 vias per square inch (i.e., 15-30 vias per square centimeter).

With multi-layer circuit design may come the options of using different types of vias to improve routing density. There are three general types of vias: standard, blind, and buried. Standard vias may go through the PCB, and may connect any of the top, bottom or inner layers. As a result, the use of standard vias may be wasteful of space on those layers which are not connected.

Blind vias may go from the outside surface of the PCB to one of the inner layers only. That is, the hole created by such blind vias may not protrude through the other side of the PCB. The via may in effect be “blind” from the other side of the board. Buried vias may only connect two or more inner layers, with no hole being visible on the outside of the board. That is, the hole created by such buried vias may be completely buried inside the PCB. In the case of PCB 100 shown in FIG. 1, for example, there may be no blind vias shown, but vias 185 and 190 may constitute buried vias. Moreover, buried via 195 and each of the stacked vias 200 shown in FIG. 1 may conventionally include a pad 210, 205 at either end of such vias 195, 200.

Microvias, as the name implies, are vias of less than or equal to about 6 mils (i.e., 150 micron) in diameter. They may often be, for example, in blind and buried vias used to create interconnections through one dielectric layer within a PCB. Microvias may also be used in blind via constructions where the outer layers of a multi-layer PCB are connected to the next adjacent signal layer.

While traditional microvia technology may allow designers to reduce layer count and improve electrical and mechanical characteristics, it is typically limited to routing on layers one to two, and one to three. Therefore, routing or escaping high I/O devices may be limited to a maximum of three layers. Stacked microvia technology may allow microvias to be stacked and provide access to multiple layers throughout the PCB. Also, stacked microvia technology provides the capability of routing or escaping standard (i.e., 1 mm) and fine pitch devices such as 0.8 mm, 0.65 mm, 0.5 mm, and 0.4 mm.

Stacked microvias, such as those 200 shown in FIG. 1, may consist, for example, of 0.004″ (i.e., 100 microns) laser drilled microvias with a 0.008″ diameter pad 205 which may maintain a solid copper plate, and may provide a planar surface and reliable connection to multiple layers within the PCB. The solid copper plate may eliminate the “dimple” when using via-in-pad technology, thus eliminating the potential for out-gassing.

FIG. 2 depicts an example of a typical HDI multi-layer circuit 250 in which embodiments of the present invention may be implemented. The HDI multi-layer circuit 250 may be formed according to IPC-2315, a standard entitled Design Guide for High Density Interconnects & Microvias (June 2000) that is jointly published by the Institute for Interconnecting and Packaging Electronic Circuits and Japan Printed Circuits Association. IPC-2315 provides an easy-to-follow tutorial on the selection of HDI and microvia design rules and structures. It addresses various considerations when designing an HDI PCB that include: design examples and processes, selection of materials, general descriptions, and various microvia technologies. IPC has selected High Density Interconnection Structures (HDIS) as a term to refer to all of the foregoing microvia technologies.

The HDI multi-layer circuit 250 shown in FIG. 2 may generally comprise a pair of ground planes 255, a pair of power planes 260, a laminate-based, multi-layer board core 265, and epoxy resin 270 between the ground planes 255 and power planes 260. It may also include a plated through-hole signal via 275, and microvias 280.

Layer stackup may be a differentiator of HDI-buildup technology. Engineers may manufacture an HDI layer stack by depositing additional microvia layers on traditional PCB cores. The industry may use HDI construction types to describe the available layer stackups. Currently, three popular HDI construction types are in use such as that which is shown in FIG. 2.

Type I construction may comprise a conventional rigid or flexible PCB core with any number of layers using through-hole vias and a single microvia layer fabricated on one or both sides of the core. Type II construction is similar, but the vias within the core may be formed before adding buildup microvia layers. Type III may have at least two microvia layers on at least one of the core's surfaces.

Several other construction types may be available. Type IV construction may comprise a “passive” core that may function as a nonelectrical shield or a thermal buffer. “Coreless” construction, which may comprise a pair of substrates laminated together, is Type V construction. Type VI construction, or colamination, may occur when the interconnect and mechanical structure may be simultaneously formed. The stacked vias and methods of manufacturing same according to embodiments of the present invention may be incorporated in any such HDI construction types.

The multitude of layer stackups that engineers may derive by combining HDI construction types and a varying number of layers may have driven the need for a simple designation scheme to identify them. The identification method is straightforward. For example, a designation of “2 (C4) 2” may indicate a layer-stack construction comprising a four-layer PCB core (C4) with two HDI (i.e., buildup) layers on the top and two on the bottom. A designation of “2 (P) 2” may indicate a Type IV construction with a passive core, two HDI layers on the top, and two HDI layers on the bottom. Again, the stacked vias and methods of manufacturing same according to embodiments of the present invention may be incorporated in any of the foregoing HDI construction types.

A microvia may be formed, not drilled like a traditional via. Designers currently may use several processes to produce microvias. Laser drilling, the most common technique, may employ a focused laser beam to form the hole. Wet/dry etching is a mass-production process that creates all vias at the same time, regardless of the number or diameter of the holes. Photo imaging coats the base substrate with a dielectric layer. Designers may also use conductive ink in microvia formation. In such a process, microvias may be formed by laser drilling, photo imaging, or insulation displacement. Designers may also form microvias mechanically, using piercing, punching, abrasive blasting, or simple drilling. Each process produces different microvia hole shapes, such as cups, positive tapers, negative tapers, and straight walls. The stacked vias and methods of manufacturing same according to embodiments of the present invention may be formed using any of the foregoing processes.

The advent of HDI technology and microvias may have also led to a new vocabulary for via structures. For example, the HDI Design Subcommittee of the IPC defines microvias as “formed blind and buried vias” that measure less than or equal to 0.15 mm and have pad diameters that measure less than or equal to 0.35 mm. Designers also may use terms such as “capture land” (i.e., the area where the microvia originates) and “target land” (i.e., the area where the microvia ends) to describe the microvia pad sizes. A landless via may have a land diameter that is the same size or smaller than the via diameter. The stacked vias and methods of manufacturing same according to embodiments of the present invention may be formed using either configuration.

At present, the size of microvias may limit their current-carrying capability. Designers may typically overcome this limitation by nesting several microvias in one large area called a plural via. Microvias that directly connect nonadjacent HDI-buildup layers are called skip vias. A variable-depth microvia is a microvia formed in one operation that penetrates two or more HDI-dielectric layers and terminates at one or more layers. Laser vias, conformal vias, filled vias, photo vias, and stud vias all may be microvias that derive their names from the processes used to form them. The stacked vias and methods of manufacturing same according to embodiments of the present invention may be formed as any such configuration.

HDI-buildup technology may offer much smaller feature sizes than standard PCB technologies. Table I compares the two technologies using relatively conservative parameters. HDI also may offer significant space reduction in component placement. HDI buildup may use microvias that designers place inside the component's surface pad. They may be blind and sometimes traverse only one or two layers in the stack, allowing for coincident placement of parts on the top and the bottom surfaces. Typical PCB technology may use through-hole vias. The via pad, or at least the drill, exists on every layer of the board. HDI may use blind and buried microvias, which occupy only the layers that they traverse. These feature-size benefits may add considerable space for routing, typically resulting in a 40% reduction in design size. Standard PCB technology may use breakout patterns and vias with stringers to get from a surface-mount pad to the inner routing layers of a design. The breakout-pattern technique greatly increases the amount of space that the component occupies. Such breakout vias may be typically through-hole and occupy space on all layers of the design. These vias also may interfere with the potential locations of parts on the opposite side of the board.

A comparison of the HDI features and conventional PCB features which may be incorporated into multi-layer circuits according to embodiments of the present invention are illustrated in Table I below.

TABLE I
A Comparison of HDI Features and Conventional PCB Features

| | Conventional | | |
|---|---|---|---|
| | PCB | Standard HDI | Advanced HDI |
| Line width (in.) | 0.005 | 0.003 | 0.0016 |
| Line spacing (in.) | 0.005 | 0.003 | 0.002 |
| Pad diameter (in.) | 0.02 | 0.003 to 0.007 | 0.0025 to 0.0035 |
| Via diameter (in.) | 0.01 | 0.003 to 0.007 | 0.0025 to 0.0035 |
| Pad pitch (in.) | 0.014 | 0.01 | 0.0093 |

To the extent they may be required in such circumstances, the stacked vias and methods of manufacturing same according to embodiments of the present invention may be easily formed by any of the foregoing methods.

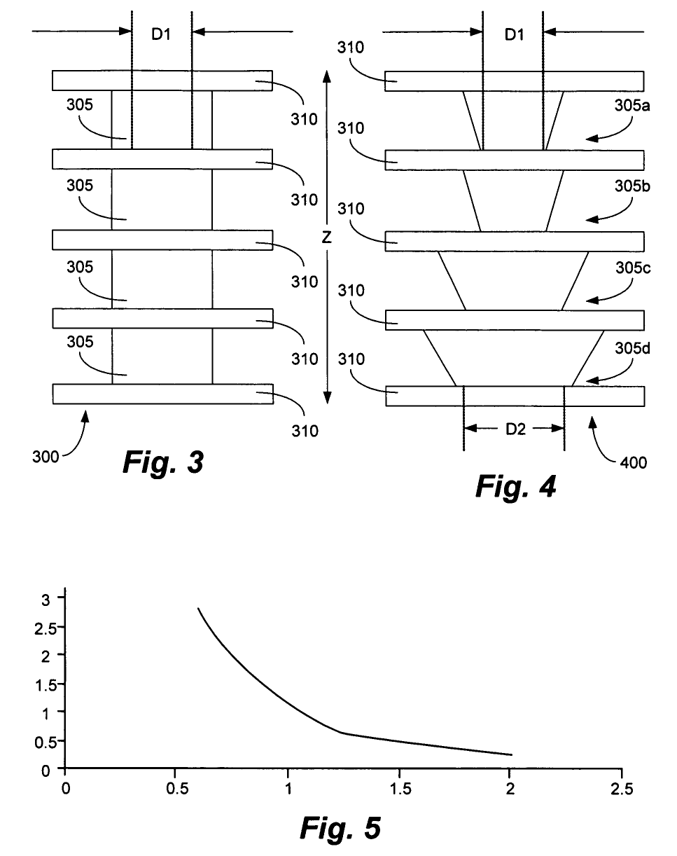

Referring now to FIGS. 3-5, further advantages of the stacked vias and methods of manufacturing same according to embodiments of the present invention will now be explained. There is depicted in FIG. 5 a graph showing a range of ratios of the diameter D2 of an innermost via in a stack of vias according to embodiments of the present invention to the diameter D1 of an outermost via. Stress at the via interface is depicted along the X-axis of FIG. 5, while the ratio of diameter D2 to D1 is depicted along the Y-axis of FIG. 5.

Stacked via configurations (e.g., as shown in FIG. 3) may be subjected to thermal stresses and strains during their assembly process and during subsequent thermal cycling. This effect may be mainly caused by the high coefficient of thermal expansion (CTE) mismatch between the dielectric materials of the substrate (i.e., α_{dielectric}) and the copper vias (i.e., α_{copper}) and the high stiffness of both materials. The mechanical strains and stresses generated by this CTE mismatch may usually be the driving force for package failure and therefore, may have to be minimized. The typical problems that may be experienced may be via cracking under too high stresses and copper failure under thermal cycling conditions. In turn, these problems may cause delamination of the via interfaces.

In the stacked via configuration 300 shown in FIG. 3, the thermal expansions of the copper vias 305 and their corresponding substrate dielectric 310 can be assumed to be different, and the thermal mismatch Δu may be approximated by the equation: Δu=Δe×D×ΔT, where:

Δe=the difference in CTE between the materials;

D=the diameter of the via; and

ΔT=temperature change.

In most mechanical structures, such thermal mismatch may be accommodated by elastic deformation, resulting sometimes in a high stress in the structure. With flip chip packages, however, the situation may be different, since the strength of the via interface may be low compared with that of usual engineering materials. With leadless components, for example, the materials of component and substrate may be comparatively so rigid that a large part of the mismatch may have to be accommodated by plastic deformation in their solder joints. In this case, repeated movement due to temperature changes may produce a cyclic stress, and fatigue failure may eventually follow.

Thermal mismatch, as a cause of delamination of the via interfaces which may in turn lead to fatigue fracture, may find its origin not only in differences in CTE, but also in differing rates of temperature change. During both assembly and operational life, the rates of heating and cooling of components and substrate may, in general, not be the same, so that temperature differences may be created, even if the CTEs are matched, and these temperature differences generate stresses. In practice, the stresses may remain fairly small, provided that no incorrect configurations have been used. However, if the rate of temperature change is very fast, as is the case in thermal shock testing, these stresses may become high.

The stress σ imparted on stacked vias under such conditions may be likewise approximated by the equation: σ=(α_{dielectric}−α_{copper})×(Tₕ−T_{c})×E_{dielectric}/A_{bottom}, where:

α_{dielectric} is the coefficient of thermal expansion of the substrate dielectric;

α_{copper} is the coefficient of thermal expansion of the copper vias;

Tₕ−T_{c} is the temperature change, or ΔT;

E_{dielectric} is the dielectric constant of the substrate; and

A_{bottom} is the bottom area of the vias.

Stacked vias have traditionally been formed with a generally uniform diameter as shown in FIG. 3. However, reliability and strength of such stacked vias may be improved by forming increasingly larger diameter vias closer to the base layers as shown in FIG. 4.

For example, merely by increasing the ratio of the diameter D1 of the outermost via 305a to the diameter D2 of the innermost via 305d from 1 to 1.5, a reduction in stress by approximately 50% may be achieved. Further increasing that ratio to about 2, as shown in FIG. 5, may realize an additional reduction in stress by another 50%. It appears that this function of stress reduction may become asymptotic with further increases in the ratio of D2 to D1.

In forming the multi-layer circuits according to embodiments of the present invention, a laser drilled microvia may be plated with copper and stacked upon another microvia creating stacked microvias, which can be utilized down multiple layers in the Z direction as shown between FIGS. 3 and 4.

Build-up multi-layer circuits may also be formed according to embodiments of the present invention by first manufacturing a multi-layer PCB having from 2 to 38 layers in the configuration shown in FIG. 2. Plated through-holes 275 may next be formed and filled with a non-conductive epoxy fill. Thereafter, an appropriate microvia layer material (e.g., FR4, RCF, Thermount, or Speedboard C) may be laminated in one or more outer layers outward from the PCB core.

Laser-drilled microvias may then be formed by any conventional means through the outer layers. The through-holes 275 may then be drilled by suitable mechanical means, and such through-holes 275 may be desmeared to roughen the dielectric surface prior to plating. The same desmearing process may be used for the microvias 280 as well. Next, the through-holes 275, microvias 280, and surface areas may be copper plated using a conventional electroless process. Finally, the outer layer circuits 255 may be pattern plated.

It may be noted that the following materials that may be used in forming the stacked vias and microvias according to embodiments of the present invention may be compatible with conventional UV lasers and CO₂ lasers: multi-functional epoxy; high-temperature epoxy; chip packaging epoxy; Thermount® epoxy (a non-woven aramid fiber reinforced substrate for printed wiring boards, the trademark for which is owned by E. I. du Pont de Nemours and Company of Wilmington, Del. USA); coated copper epoxy; low loss enhanced multi-functional epoxy; BT epoxy; JEDEC chip packaging BT epoxy; non-MDA polyimide; toughened polyimide; and cyanate ester. By contrast, with plasma layers, only Thermount epoxy and coated copper epoxy may be compatible.

Using such materials and processes, the stacked vias according to embodiments of the present invention may be formed by providing a base or core layer; forming a plurality of additional layers electrically coupled to and outward from that base or core layer; and forming a plurality of stacked vias within adjacent ones of those additional layers such that the diameter D2 of one of the stacked vias within an inner more one of the additional layers (i.e., layers which are relatively closer to the base layer) is greater that the diameter D1 of another of the stacked vias within an outer more one of the additional layers (i.e., layers which are relatively farther from the base layer).

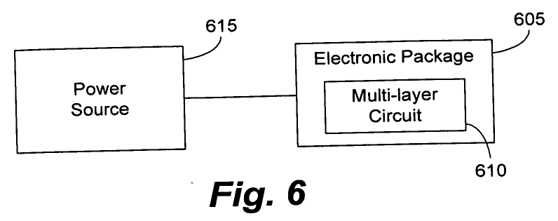

A system according to embodiments of the present invention is depicted in FIG. 6. Such a system includes an electronic package 605 containing a multi-layer circuit 610 as shown an described herein before. That is, multi-layer circuit 610 may comprise a base layer, a plurality of additional layers electrically coupled to and outward from the base layer, and a plurality of stacked vias formed within adjacent ones of the additional layers such that a diameter D2 of one of the stacked vias within an inner more one of the additional layers is greater than a diameter D1 of another of the stacked vias within an outer more one of the additional layers. The system may further comprise at least one power source 615 coupled to the electronic package 605 to provide power to the electronic package 605 and multi-layer circuit 610.

The invention has been described in detail with respect to various embodiments, and it will now be apparent from the foregoing to those skilled in the art that changes and modifications may be made without departing from the invention in its broader aspects. The invention, therefore, as defined in the appended claims, is intended to cover all such changes and modifications as fall within the true spirit of the invention.

What is claimed is:

1. A multi-layer circuit, comprising:
a base layer;
a plurality of additional layers electrically coupled to and outward from said base layer; and
a plurality of stacked vias formed within adjacent ones of said additional layers such that a diameter D2 of one of said stacked vias within an inner more one of said additional layers is greater than a diameter D1 of another of said stacked vias within an outer more one of said additional layers.

2. The multi-layer circuit according to claim 1, wherein the ratio of the diameter D2 of one of said stacked vias within an inner more one of said additional layers to the diameter D1 of another of said stacked vias within an outer more one of said additional layers is about 1.5.

3. The multi-layer circuit according to claim 1, wherein the ratio of the diameter D2 of one of said stacked vias within an inner more one of said additional layers to the diameter D1 of another of said stacked vias within an outer more one of said additional layers is about 2.0.

4. The multi-layer circuit according to claim 1, wherein the plurality of additional layers comprise three, and the diameter of a first one of said stacked vias within an inner most one of said additional layers is greater than the diameter of a second one of said stacked vias within the next inner most one of said additional layers, which, in turn, is greater than the diameter of a third one of said stacked vias within the next inner most one of said additional layers.

5. The multi-layer circuit according to claim 1, wherein the plurality of additional layers comprises more than three additional layers, and the ratio of the diameter of each adjacent pair of said stacked vias progressing from an inner most one of said additional layers to an outer most one of said additional layers is greater than 1.0.

6. The multi-layer circuit according to claim 1, wherein the plurality of additional layers comprises more than three additional layers, and the ratio of the diameter D2 of a stacked via within an inner most one of said additional layers to the diameter D1 of a stacked via within an outer most one of said additional layers is between about 1.5 to 2.0.

7. The multi-layer circuit according to claim 1, wherein the plurality of additional layers comprises more than three additional layers, and the ratio of the diameter D2 of a stacked via within an inner most one of said additional layers to the diameter D1 of a stacked via within an outer most one of said additional layers is greater than 2.0.

8. A system comprising:
an electronic package containing a multi-layer circuit including:
a base layer;
a plurality of additional layers electrically coupled to and outward from said base layer; and
a plurality of stacked vias formed within adjacent ones of said additional layers such that a diameter D2 of one of said stacked vias within an inner more one of said additional layers is greater than a diameter D1 of another of said stacked vias within an outer more one of said additional layers; and
at least one power source coupled to said electronic package to provide power to said electronic package and multi-layer circuit.

9. The system according to claim 8, wherein said electronic package comprises a flip chip package.

10. The system according to claim 9, wherein said flip chip package comprises a high density interconnect (HDI) package.

11. The system according to claim 9, wherein said flip chip package comprises a micro ball grid array (μBGA) package.

12. The system according to claim 9, wherein said flip chip package comprises a micro surface mount technology (MSMT) package.

13. The system according to claim 9, wherein said flip chip package comprises a slightly larger than integrated circuit carriers (SLICC) package.

14. The system according to claim 8, wherein said electronic package comprises a printed circuit board (PCB).

15. A method of forming an electronic package containing a multi-layer circuit, comprising:
providing a base layer;
forming a plurality of additional layers and electrically coupling same to and outward from said base layer; and
forming a plurality of stacked vias within adjacent ones of said additional layers such that a diameter D2 of one of said stacked vias within an inner more one of said additional layers is greater that a diameter D1 of another of said stacked vias within an outer more one of said additional layers.

16. The method according to claim 15, wherein the ratio of the diameter D2 of one of said stacked vias within an inner more one of said additional layers to the diameter D1 of another of said stacked vias within an outer more one of said additional layers is about 1.5.

17. The method according to claim 15, wherein the ratio of the diameter D2 of one of said stacked vias within an inner more one of said additional layers to the diameter D1 of another of said stacked vias within an outer more one of said additional layers is about 2.0.

18. The method according to claim 15, wherein the plurality of additional layers comprise three, and the diameter of a first one of said stacked vias within an inner most one of said additional layers is greater than the diameter of a second one of said stacked vias within the next inner most one of said additional layers, which, in turn, is greater than the diameter of a third one of said stacked vias within the next inner most one of said additional layers.

19. The method according to claim 15, wherein the plurality of additional layers comprises more than three additional layers, and the ratio of a diameter of each adjacent pairs of said stacked vias progressing from an inner most one of said additional layers to an outer most one of said additional layers is greater than 1.0.

20. The method according to claim 15, wherein the plurality of additional layers comprises more than three additional layers, and the ratio of the diameters of a stacked via within the inner most one of said additional layers to a stacked via within the outer most one of said additional layers is between about 1.5 to 2.0.

21. The method according to claim 15, wherein the plurality of additional layers comprises more than three additional layers, and the ratio of the diameters of a stacked via within the inner most one of said additional layers to a stacked via within the outer most one of said additional layers is greater than 2.0.

22. The method according to claim 15, further comprising forming a flip chip package.

23. The method according to claim 15, further comprising forming a high density interconnect (HDI) package.

24. The method according to claim 15, further comprising forming a micro ball grid array (μBGA) package.

25. The method according to claim 15, further comprising forming a micro surface mount technology (MSMT) package.

26. The method according to claim 15, further comprising forming a slightly larger than integrated circuit carriers (SLICC) package.

27. The method according to claim 15, further comprising forming a printed circuit board (PCB).
